(19) United States
(12) Patent Application Publication
(10) Pub. No.: US 2011/0081851 A1
(43) Pub. Date: Apr. 7, 2011

(54) FLOW CONTROL SYSTEM AND METHOD

(76) Inventors: John P. Franz, Houston, TX (US); Sarah Nicole Anthony, Houston, TX (US)

(21) Appl. No.: 12/573,800

(22) Filed: Oct. 5, 2009

(51) Int. Cl. H05K 5/00; F24F 7/00

(52) U.S. Cl. 454/184; 454/254; 137/1

(57) ABSTRACT

Embodiments of a flow control system and method are disclosed. An exemplary method may include causing air to move along an air flow path through at least one inlet formed in the housing over at least a portion of an electronic device, causing the air to move adjacent one or more component of the electronic device, and causing the air to move through at least one outlet formed in the housing. The method may also include adjusting at least one baffle in the air flow path between different positions based on configuration and power requirements of the electronic device to control the air flow through the housing along the air flow path.

### BACKGROUND

Blowers and fans find application in a wide variety of computer systems and other electronic devices, to help dissipate heat generated during operation of the computer system or other electronic devices. If not properly dissipated, heat generated during operation can shorten the operating life of various electronic components and/or generally result in poor performance of the computers or other electronic devices. Various blowers are available, and when used for thermal management of computer systems and other electronic devices, these blowers are typically positioned to blow air across one or more heat sink and out an opening formed through the housing to dissipate heat into the surrounding environment.

Sizing the blower is important during development of these systems. Developers also have to consider cost, size constraints, and acoustics (e.g., noise generated by the blower). Overcooling may result in excessive noise. In large rack-based computer systems, the number and/or size of fans needed to cool all of the components can make the room so noisy that technicians only enter the room on an as-needed basis (e.g., to make repairs, upgrades, etc.). Similarly, overcooling may result in wasted energy and the associated costs.

### BRIEF DESCRIPTION OF THE DRAWINGS

FIGS. 1a-1b are perspective views of an exemplary electronics enclosure, where (a) illustrates balanced flow, and (b) illustrates unbalanced flow.

FIGS. 2a-2b are perspective views of an exemplary flow control system, where (a) illustrates baffles in a first position, and (b) illustrates baffles in a second position.

FIG. 3a-3b are perspective views of the exemplary flow control system from FIGS. 2a-2b as it may be implemented in the electronics enclosure shown in FIGS. 1a-1b, where (a) illustrates baffles in a first position, and (b) illustrates baffles in a second position.

FIGS. 4a-4b are partial perspective views showing another exemplary embodiment of the flow control system having an exemplary optical sensor.

FIGS. 5a-5b are simplified top plan views of an alternate embodiment of an exemplary flow control system including a sensor and drive motor for operating the baffles, where (a) illustrates baffles in a first position, and (b) illustrates baffles in a second position.

### DETAILED DESCRIPTION

Blade infrastructure with aggregate cooling require all pressure drop paths to be balanced. Balancing pressure drop and resulting flow volume is challenging in a server with varying parallel impedances that are dependent upon configuration. If this pressure balance is not properly set, the ramifications can extend beyond the server and impact all blade infrastructure components with high fan speed (excessive power and noise) and possibly system shut down or component damage. Rack mount servers are continuing to cool more with less fans thus resulting in similar flow balancing dilemmas caused by un-populated components.

The systems and methods disclosed herein provide an adjustable aperture in the server that can be positioned where needed as configuration varies. This invention is not however only blade specific. Exemplary embodiments enable an adjustable baffle configuration for the server to help balance the pressure drop and meet changing flow requirements due to memory type (thin vs. thick), memory population or count and power level.

Briefly, exemplary embodiments of a flow control system disclosed herein may be used to dissipate heat in computers or other electronic devices, such as may be implemented in rack systems. In an exemplary system, a blower (array of blowers, or other suitable configuration) may be located adjacent the computer or other electronic devices in a rack system to remove heat generated in the chassis to a physically remote environment (e.g., outdoors). An adjustable baffle may be provided to assist in controlling or balancing pressure drop and the resulting air flow volume to accommodate various impedances based on varying configurations and/or operating conditions.

Accordingly, the flow control system may help reduce the energy consumption, efficiency, and costs associated with cooling computer systems and other electronic devices, and may also improve acoustics during operation. In exemplary embodiments, the air flow may also be regulated and remotely controlled, if desired, to customize operation rate and/or may be readily upgraded to accommodate changes in conditions (e.g., operating temperature) and/or system configuration (e.g., type and/or arrangement of components in a rack system).

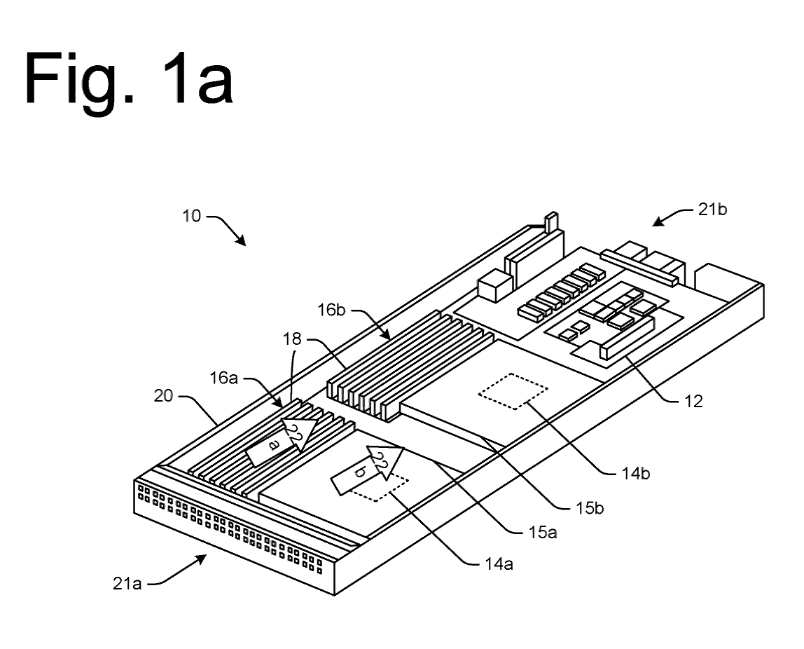

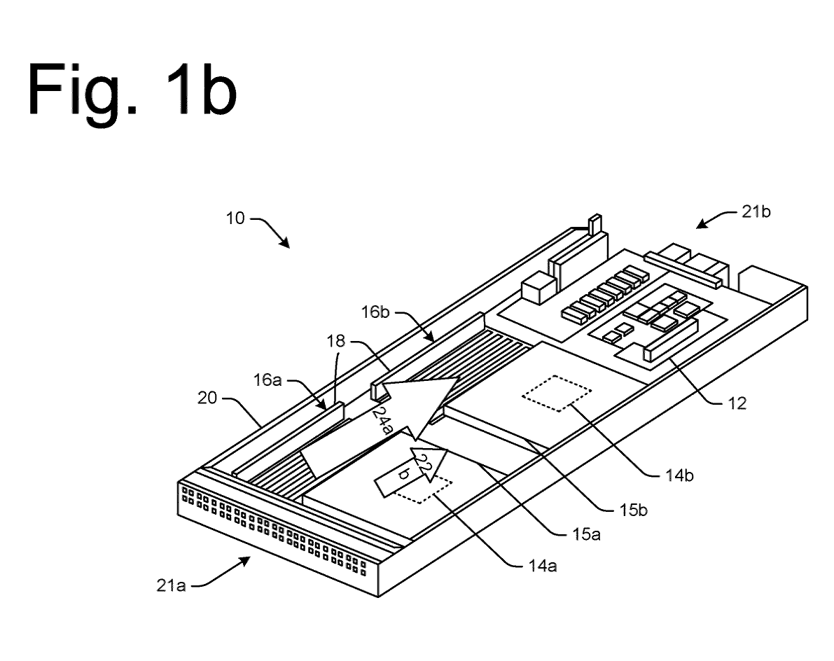

FIGS. 1a-1b are perspective views of an exemplary electronics enclosure 10, where (a) illustrates balanced flow, and (b) illustrates unbalanced flow. The electronics enclosure 10 may be a blade server or other blade device (also referred to as a “blade”) implemented in a rack system. Rack systems are well known and widely used in computing and electronics environments. An exemplary rack system (not shown) may include a plurality of blades that are mounted within a housing. The blades may be any suitable size enclosures and may be manufactured of any suitable material, such as, e.g., a plastic or metal enclosure suitable for mounting in the housing of the rack system.

Each blade may house electronic and other heat-generating devices. For example, the blade or electronics enclosure 10 may house a PC board 12 including one or more processing units or processors 14a, 14b, one or more memory bank 16a, 16b populated with one or more memory devices 18, and other devices and components mounted to, connected to, or positioned within the electronics enclosure 10. For example, blade servers may also include data storage devices (e.g., hard disk drives, compact disc (CD) or digital versatile disc (DVD) drives, etc.) and operate in a communications network, and therefore the blade services may also include suitable network connection interface(s). Still other devices and components may also be mounted on or otherwise connected to the PC board, as is readily apparent to one having ordinary skill in the computer and electronic arts. During operation, one or more of these components (e.g., the processors 14a, 14b and the memory devices 18) may generate heat.

In an exemplary embodiment, one or more heat sink may also be provided in the electronics enclosure 10 to aid in collecting heat and “wicking” the heat away from the heat-generating components and into the path of air flow through the chassis. In FIGS. 1a and 1b, CPU heat sinks 15a and 15b are shown. Heat sinks are well understood in the art, and may be manufactured of a thermally conductive material (e.g., metal or metal alloys) configured to readily absorb heat in one area and dissipate the absorbed heat in another area. In an exemplary embodiment, the thermally conductive material is formed as a plurality of “fins,” but other embodiments are also contemplated.

The electronics enclosure 10 also includes openings or apertures formed in an air guide (or guide), cover, or housing 20 and configured to direct air flow through an inlet 21a along a flow path (illustrated by arrows 22a, 22b in FIG. 1a and arrows 24a, 24b in FIG. 1b) from an external fan or blower (not shown) adjacent one or more of the heat sinks 15a and 15b and/or the electronics components (e.g., memory devices 18) housed within the electronics enclosure 10, and then out through one or more exhaust opening or outlet 21b (e.g., on the opposite side of the housing).

It is noted that the electronics enclosure 10 is shown only as an example of one such configuration. The inlet and outlet may be provided on either the front or the back and/or on the sides and/or top/bottom of the housing 20. Likewise, the systems and methods described herein are not limited to use with any particular type or configuration of rack system, computer, or other electronic device. In an exemplary embodiment, one or more exhaust pump may also be operated to assist air flow.

In any event, during operation cooling air is drawn through a front portion of the rack system, through the electronics enclosure 10 and out the air flow opening formed through the back-end of the electronics enclosure 10. Drawing cooler air through the front of the electronics enclosure 10, past the heat-generating components and out the back-end of the electronics enclosure 10 functions to reduce or altogether remove heat from the electronics devices (e.g., the CPU 14a, 14b and memory devices 18).

When CPU-memory, architecture includes the processor and memory bank positioned side-by-side, e.g., as illustrated in FIGS. 1a and 1b, air flow passes through the electronics enclosure 10 at the same time and creates a parallel flow structure, as illustrated by the arrows 22a, 22b and 24a, 24b. When the memory banks 16a, 16b are fully populated, as shown in FIG. 1a, the air flow is substantially equal or balanced between the memory banks 16a, 16b and the CPU heat sinks 15a, 15b. This is illustrated by the substantially same size air flow arrows 22a and 22b in FIG. 1a.

However, the memory banks 16a, 16b may also be partially populated, as shown in FIG. 1b, which may cause a lower pressure drop through the memory banks 16a, 16b as compared to the air flow past the CPU heat sink(s). Additionally, memory capacity (e.g., 4 GB versus 8 GB versus 16 GB, etc) also impacts memory module thickness. For example, larger memory may be provided as “stacked” memory and/or be provided with heat spreaders, each of which serve to increase the size of the memory devices 18. In addition, higher power devices are also typically thicker than lower power devices, and thus further compounds the cooling issue. This variety in configurations, populations, and operating parameters makes it difficult to balance air flow between the CPU heat sinks 15a, 15b and the memory banks 16a, 16b, as illustrated by the different size arrows 24a, 24b in FIG. 1b. The inability to balance air flow may result in excessive use of the blower (and corresponding power usage) to maintain the electronics enclosure 10 in the desired temperature range for the installed components.

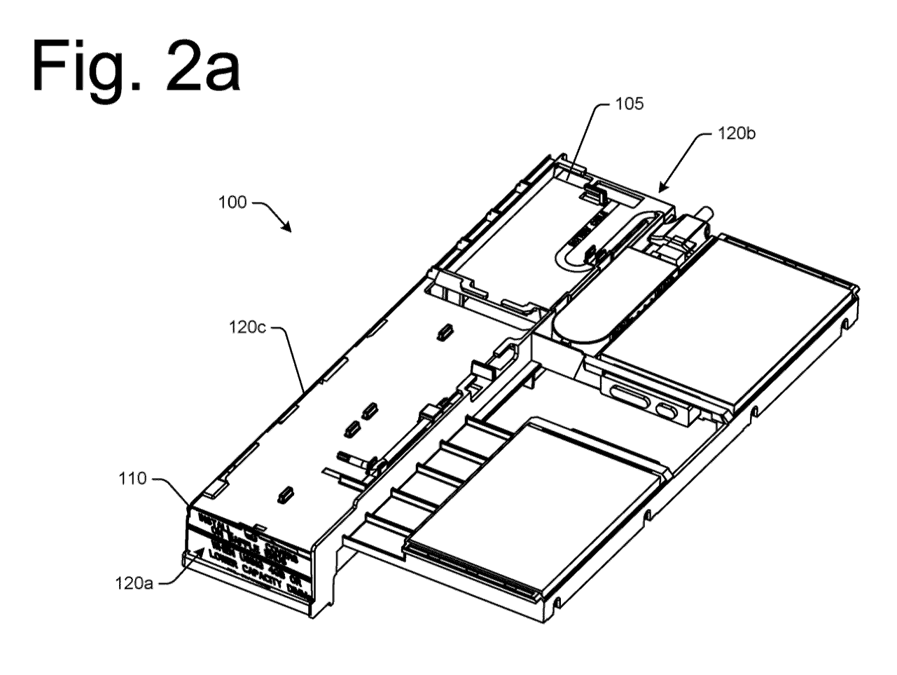

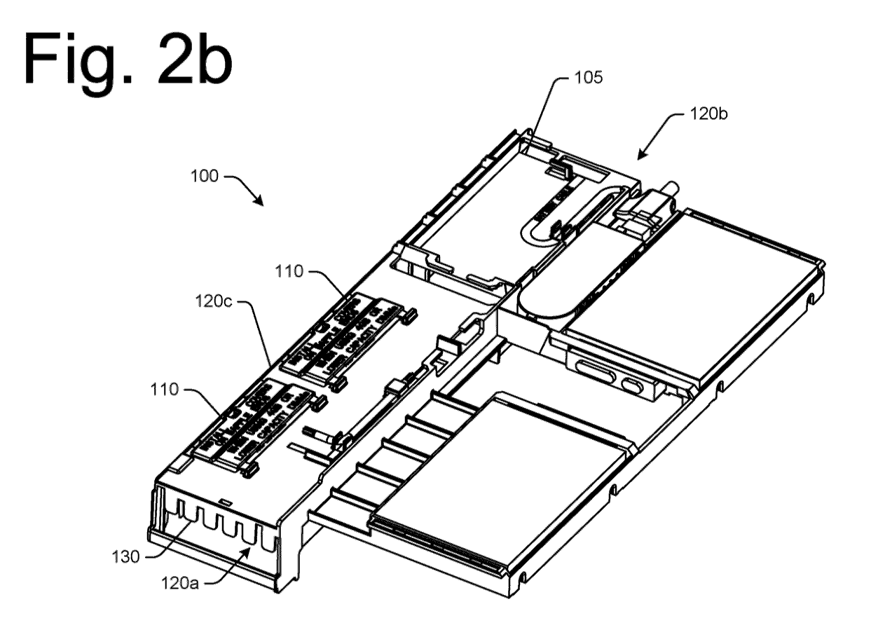

As will be readily appreciated from the exemplary embodiments discussed in more detail below, a flow control system 100 (see, e.g., FIG. 2a, 2b) enables variable, and hence more efficient, heat-dissipation in electronics enclosures 10 than would be possible if the blower had to be sized and continually operated to provide maximum heat-removal capability regardless of the configuration of components in the electronic device. Likewise, components having different heat dissipation requirements may be installed in the electronics enclosure 10 at different times without having to change the size blower provided for the rack system.

FIGS. 2a-2b are perspective views of an exemplary flow control system 100, where (a) illustrates baffles 110 in a first position, and (b) illustrates baffles 110 in a second position. In an exemplary embodiment, the flow control system 100 may include a housing 105 provided over at least a portion of an electronic device (e.g., the electronics enclosure 10 shown in FIGS. 1a and 1b). At least one inlet 120a and at least one outlet 120b are each formed in the housing 105. The at least one inlet 120a and at least one outlet 120b provide air flow from an external source (e.g., a fan or blower, not shown) adjacent one or more component (e.g., the CPU heat sinks and memory banks) of the electronic device, for example, as described above with reference to FIGS. 1a and 1b. The housing 105 may cover all sides of a memory bank in order to direct flow through the memory bank and reduce bypass. With a constant volume of air, this reduction of air flow through the memory bank results in a larger volume of air available in other parts of the system, and substantially balancing the air flow through the electronics enclosure regardless of the population of memory devices in the memory bank, power requirements, and configuration.

At least one baffle 110 is provided in the air flow path. In the example shown in FIGS. 2a and 2b, an adjustable baffle 110 is provided for the inlet 120a and the outlet 120b, and between each memory bank (e.g., at 120c beneath the housing 105). The adjustable baffle 110 is movable between different positions to control air flow through the housing along the air flow path. For purposes of illustration, the adjustable baffle 110 is shown in a first position covering the inlet 120a and outlet 120b in FIG. 2a, and the adjustable baffle 110 is shown in a second position leaving the inlet 120a and outlet 120b uncovered in FIG. 2b. Of course one or more of the baffles may be installed and/or uninstalled depending on the desired air flow. In addition, the baffles 110 may also be installed in between the memory banks, e.g., at 120c.

When the baffles 110 are open, a plurality of tabs 130 may be provided over the openings formed in the inlet 120a and outlet 120b. These tabs 130 may serve to create air flow similar to what would exist without the flow control system 100 if the memory banks were fully populated with thinner memory modules. Of course, it is noted that any number, size, and shape of tabs 130 may be implemented. In other embodiments, the tabs 130 may be altogether omitted to achieve desired flow characteristics.

In other embodiments, the baffles 110 may be partially installed or partially uninstalled (e.g., by sliding up/down or side-to-side). In still other embodiments (not shown), the baffles may slide between the memory banks and the CPU heat sinks to cover/uncover all or a portion of the memory banks and/or one or more opening (not shown) formed near the CPU heat sinks.

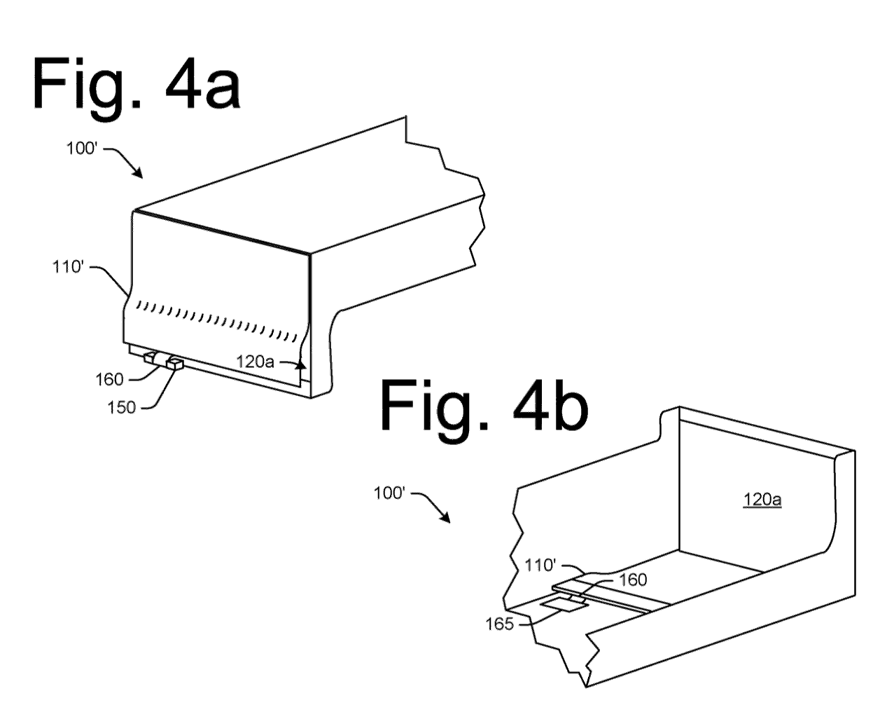

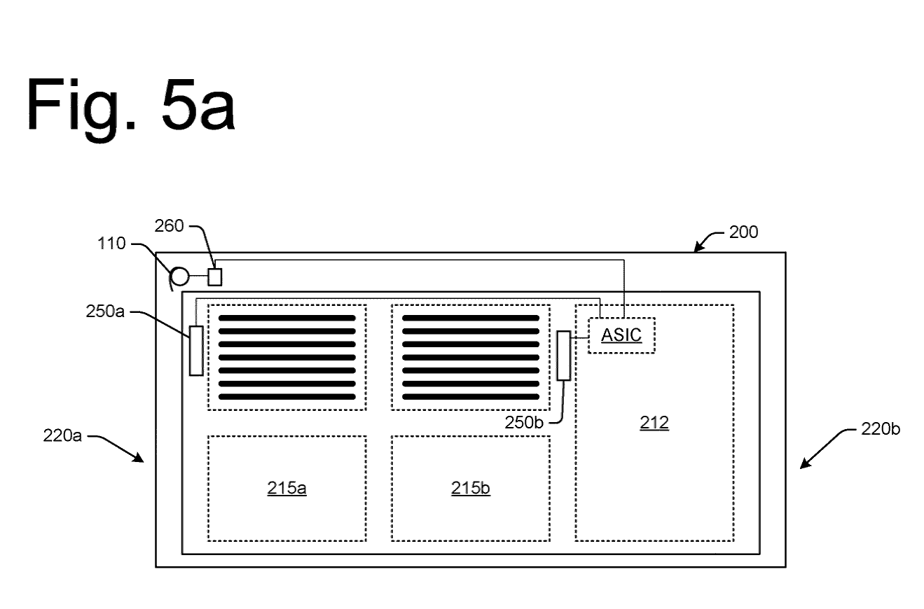

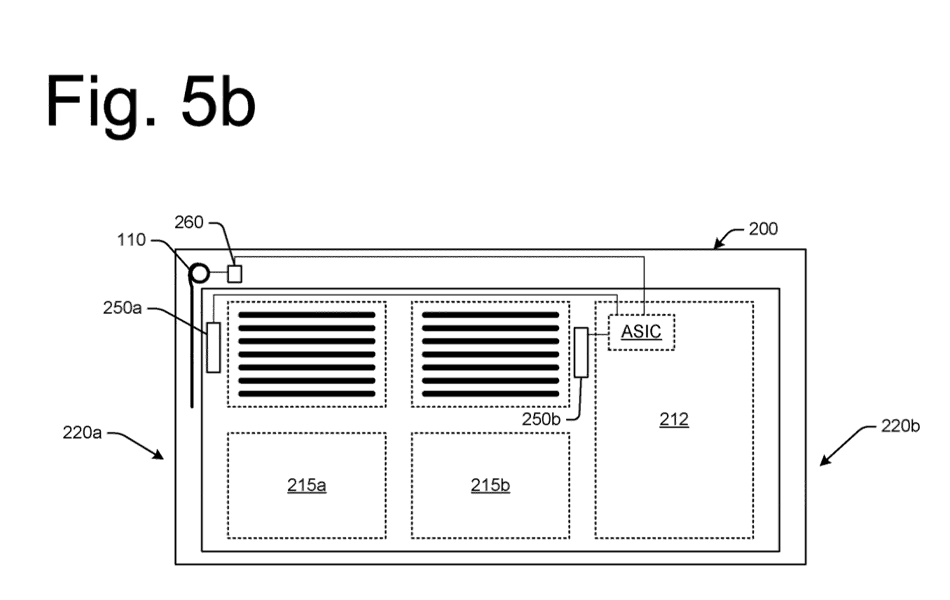

Of course design variations of the baffles 110 are also possible. Examples may include a roll-up baffle (see, e.g., FIGS. 5a and 5b), a hinged baffle, and/or a spring-assisted baffle. Other examples may include the use of a thin, flexible material (e.g., Mylar®) that can incorporate a flap that operates as a “living” hinge (see, e.g., FIGS. 4a-4b). Such an embodiment allows almost “zero” thickness for improved user options in space constrained systems. The flap may be held in a closed (flap down) position with a tab 160 and slot 165 system as shown in FIGS. 4a-4b and then folded inside the housing and out of the way when the aperture is opened (flap up).

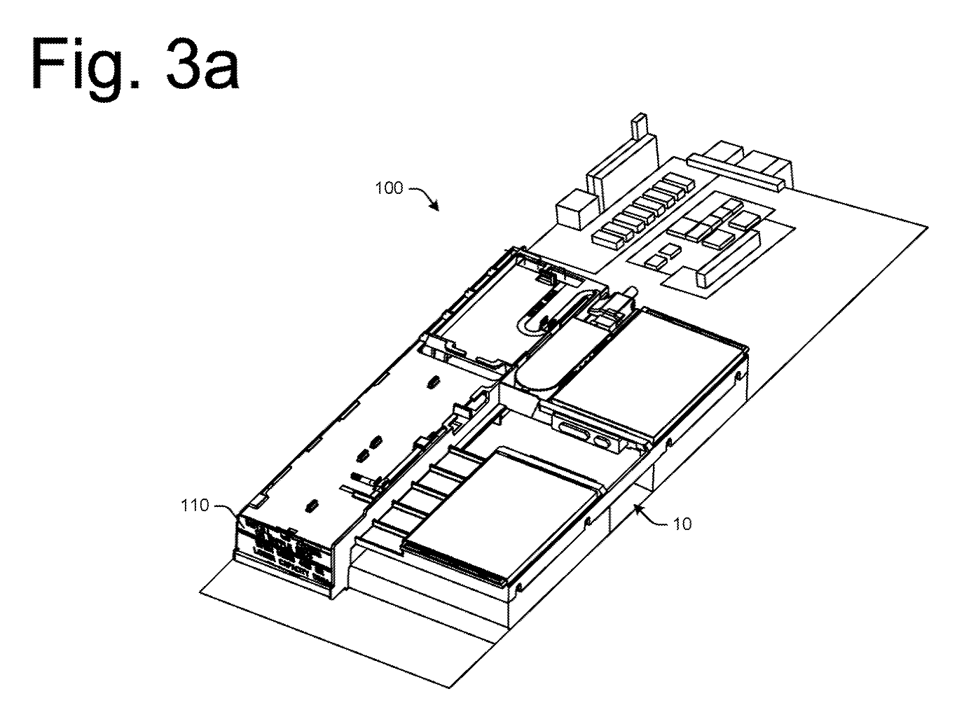

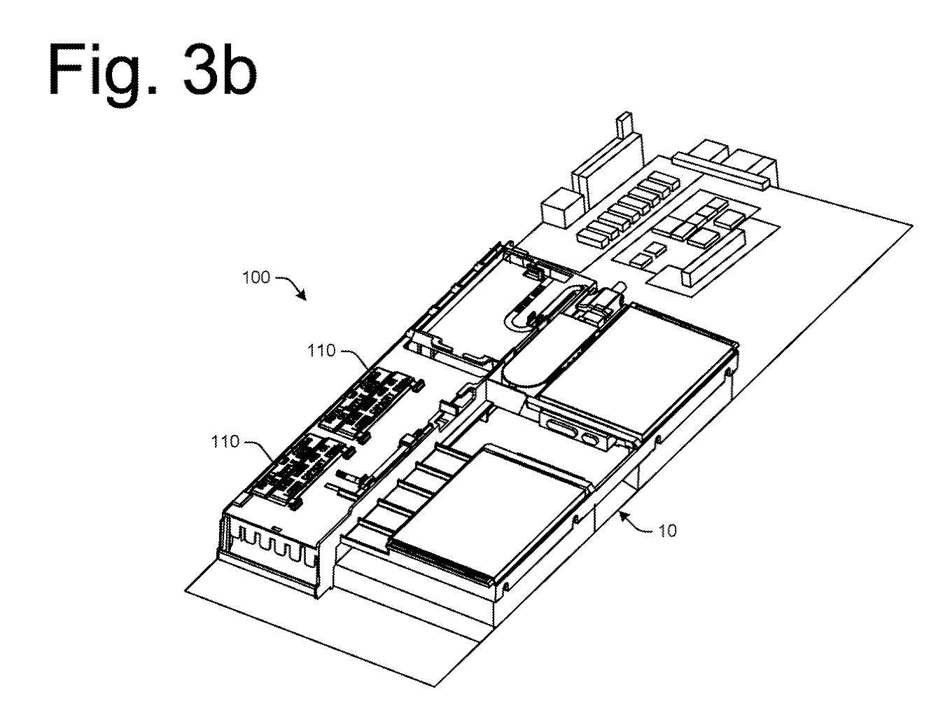

FIG. 3a-3b are perspective views of the exemplary flow control system 100 from FIGS. 2a-2b as it may be implemented in the electronics enclosure 10 shown in FIGS. 1a-1b, where (a) illustrates baffles 110 in a first position, and (b) illustrates baffles in a second position.

As noted above, leaving the memory banks open when the memory bank is not fully populated with memory devices may result in imbalanced air flow between the memory banks and the CPU heat sinks. This imbalance may cause excessive use of the blower (and hence power consumption), and/or may starve air to the fixed impedances (e.g., the processor heat sinks). Simply covering the memory banks with a baffle helps reduce excessive bypass around a fully populated bank of memory, but does not help with different memory configurations (e.g., thin memory devices or partial memory population).

Alternatively, the user can install blanks or fillers that represent the flow restriction of the memory modules. This solution is expensive due to cost of each blank used to fill the empty memory slots, and does not take into account all memory thickness options because the blank can only be designed to one or a few thicknesses. Furthermore the blanks may only provide marginal benefits when a memory bank is not fully populated. In a fully populated memory bank (no blanks installed) the pressure difference variability still exists with thin or thick memory modules.

Instead, the flow control system 100 may be implemented for variable populations, variable load conditions, and/or different configurations of components in the electronics enclosure 10 to provide consistent, substantially similar, or balanced air flow. Accordingly, the systems and methods allow for adjustment of the memory zone pressure drop restriction and accommodate variations related to configuration (e.g., memory thickness, memory population and power requirements of the devices).

Exemplary embodiments therefore reduce power consumption for the blower by not “wasting” air flow through empty memory banks or wide spaces caused by thin memory components. Instead, air flow is balanced between the memory banks and the CPU heat sinks and other components in the electronics enclosure 10. Conversely with different size memory and full population, air flow is diverted back into the memory bank while maintaining pressure drop for the whole system.

The flow control system 100 may be implemented with fewer parts than blanks, and permits a wider range of functionality. The system results in lower material cost and less power consumption (and corresponding operational costs) while offering a wide performance range. For purposes of illustration and without intending to be limiting, the following examples show power savings during preliminary testing of the flow control system.

In the first example at 25° C. ambient operating temperature, six 2 GB DIMM modules were installed in the blade and the flow control system resulted in a 9.0 W power savings due to fan speed reduction from 11500 rpm (without the flow control system) to 9000 rpm (using the flow control system).

In the second example at 25° C. ambient operating temperature, twelve 4 GB DIMM modules were installed in the blade and the flow control system resulted in a 5.8 W power savings due to fan speed reduction from 11000 rpm (without the flow control system) to 9300 rpm (using the flow control system).

In the third example at 35° C. ambient operating temperature, six 2 GB DIMM modules were installed in the blade and the flow control system resulted in a 25.1 W power savings due to fan speed reduction from 16000 rpm (without the flow control system) to 12500 rpm (using the flow control system).

In the fourth example at 35° C. ambient operating temperature, twelve 4 GB DIMM modules were installed in the blade and the flow control system resulted in a 6.4 W power savings due to fan speed reduction from 14000 rpm (without the flow control system) to 13000 rpm (using the flow control system).

In further embodiments, the flow control system 100 may be operated based on feedback from one or more sensor to maintain consistent and efficient operation regardless of configuration of the electronic device. For example, FIGS. 4a-4b are partial perspective views showing another exemplary embodiment of the flow control system 100′ having an exemplary optical sensor 150. FIG. 4a shows the flow control system 100′ from a top perspective view; and FIG. 4b shows the flow control system 100′ from a bottom perspective view (e.g., “flipped” from FIG. 4a). The optical sensor 150 may be positioned adjacent a flap-type baffle 110′ to detect the position of the baffle (e.g., whether the baffle 110′ is in a raised or lowered position). In this embodiment, the optical sensor 150 detects the presence or absence of a tab 160.

Still other exemplary sensors may include, but are not limited to, temperature or heat sensing devices, air flow sensing devices, pressure sensing devices, and power-consumption sensors, to name only a few examples. Exemplary embodiments are discussed in more detail below with reference to FIGS. 5a-5b.

FIGS. 5a-5b is a simplified top plan view of an alternate embodiment of an exemplary flow control system 200 including a sensor 250a, 250b and drive motor 260 for operating the baffles 210, where (a) illustrates baffles 210 in a first position, and (b) illustrates baffles 210 in a second position. It is noted that 200-series reference numbers are used to refer to like components in the previous figures, and therefore may not be reintroduced in the discussion of FIGS. 5a and 4b.

In an exemplary embodiment, one or more sensor 250a, 250b may be implemented to monitor one or more operating condition (e.g., heat being generated as detected by temperature sensors) or configuration (e.g., memory component population as correlated with temperature or air flow rate). Input from the sensor(s) 250a, 250b may be processed using suitable firmware/software/program code and/or a suitable integrated circuit (e.g., application specific integrated circuit (ASIC) in FIG. 5a-5b) and used to notify the user of an operating condition (or change in operating condition). Notification may be via a light, a control panel, or remote notification (e.g., email). Notification may also include instructions for the user to reconfigure the flow control system 200 based on current operating conditions. For example, a lookup table may be implemented to identify predetermined operating conditions (e.g., pressure, temperature, etc.) and the corresponding correction (e.g., position of the baffle which will improve air flow).

One or more actuator (e.g., drive motor 260) may also be provided to control operation of the flow control system 200 in response to feedback from the sensor(s) 250a, 250b. During operation, firmware residing in memory and executing by processor (e.g., ASIC on the PC board 212) may operate the flow control system 200 to automatically adjust the position of the baffle(s) 210. For example, firmware may be executed operate one or more drive motor 260 to open/close a roll-up baffle as can be seen in the illustrations shown in FIGS. 5a and 5b.

Feedback from these or other sensor(s) may also be used to operate the blower (not shown) at different speeds, shutting off one or more of the blowers when not needed, and/or varying other settings, to name only a few examples of operation.

Such implementations reduce energy use when higher air flow rates are not needed, but if more heat is generated (e.g., depending on the operating conditions, configuration, etc.), additional air flow may be provided to more quickly and effectively remove heat without adversely affecting operation.

Although particular configurations and numbers of components have been described herein for the flow control system 100, any number of components may be implemented in any suitable configuration. The type and number of components and the configuration will depend on a variety of design characteristics of the flow control system and/or the system in which the flow control system is being implemented, as will be readily appreciated by those having ordinary skill in the art after becoming familiar with the teachings herein.

The flow control system described herein offers a number of advantages. Such advantages include, but are not limited to, optimum use of space and the possibility of reducing product size, design flexibility, improved acoustics during operation, fewer or no moving parts in some embodiments, potential energy and cost savings, and the opportunity to reduce overall power requirements.

It is noted that the use of positive pressure is implied in the above description. That is, the air blows on or past something. However, the above description applies equally to the inlet air stream, which can be used to create a vacuum as well as positive pressure.

It is also noted that the exemplary embodiments discussed above are provided for purposes of illustration. Still other embodiments are also contemplated. Although the systems and methods are described with reference to computer systems and rack-based computer systems in particular, in other exemplary embodiments the systems and methods may be implemented for other electronic devices, such as, peripheral devices for computers, video and audio (AV) equipment, etc. Likewise, the systems and methods may be implemented in household or consumer electronics.

In addition to the specific embodiments explicitly set forth herein, other aspects and embodiments will be apparent to those skilled in the art from consideration of the specification disclosed herein. It is intended that the specification and illustrated embodiments be considered as examples only.

1. A flow control method comprising:
causing air to move along an air flow path through at least one inlet formed in the housing over at least a portion of an electronic device, causing the air to move adjacent one or more component of the electronic device, and causing the air to move through at least one outlet formed in the housing; and
adjusting at least one baffle in the air flow path between different positions based on configuration and power requirements of the electronic device to control the air flow through the housing along the air flow path.

2. The method of claim 1, wherein adjusting the at least one baffle provides substantially similar air flow over a memory bank of the electronic device regardless of varying populations of memory devices in the memory bank.

3. The method of claim 1, wherein adjusting the at least one baffle balances air flow over at least one memory bank and at least one processor of the electronic device.

4. The method of claim 1, further comprising moving the at least one baffle to different positions in response to feedback from at least one sensor.

5. The method of claim 1, further comprising automatically notifying a user which of a plurality of positions to move the at least one baffle based on configuration of the electronic device.

6. The method of claim 1, further comprising automatically notifying a user when the at least one baffle should be moved to another position based on a change in configuration of the electronic device.

7. The method of claim 1, further comprising:
receiving input from at least one sensor, the input corresponding to a configuration of the electronic device; and
automatically moving the at least one baffle to different positions in response to the input.

8. A flow control system, comprising:
a guide adjacent at least a portion of an electronic device;
at least one inlet and at least one outlet each formed in the guide, the at least one inlet and at least one outlet causing air to flow from an external source adjacent one or more component of the electronic device; and
at least one adjustable baffle provided in an air flow path, the at least one adjustable baffle movable between different positions to control air flow through the guide along the air flow path.

9. The system of claim 8, wherein the at least one adjustable baffle is provided adjacent the at least one inlet formed in the guide.

10. The system of claim 8, wherein the at least one adjustable baffle is provided adjacent the at least one outlet formed in the guide.

11. The system of claim 8, wherein the at least one adjustable baffle is provided within the guide.

12. The system of claim 8, further comprising a plurality of tabs provided over the at least one inlet formed in the guide, the plurality of tabs configured to control air flow through the guide.

13. The system of claim 8, further comprising a plurality of tabs provided over the at least one outlet formed in the guide, the plurality of tabs configured to control air flow through the guide.

14. The system of claim 8, further comprising a plurality of tabs provided within the guide, the plurality of tabs configured to control air flow through the guide.

15. The system of claim 8, wherein the guide covers a memory bank of the electronic device, the at least one adjustable baffle movable to different positions to provide substantially similar air flow over the memory bank regardless of varying populations of memory devices in the memory bank.

16. The system of claim 8, wherein the guide covers at least one memory bank and at least one processor, the at least one adjustable baffle movable to different positions to balance air flow over the at least one memory bank and the at least one processor.

17. The system of claim 8, wherein the at least one adjustable baffle is automatically moved to different positions in response to input from at least one sensor.

18. A flow control system comprising:
means for covering at least a portion of an electronic device;
means for causing air to flow along an air flow path including at least one inlet formed in the means for covering, at least one component of the electronic device, and at least one outlet formed in the means for covering; and
means for adjusting the air flow path based on configuration and power requirements of the electronic device.

19. The system of claim 18, wherein adjusting the at least one baffle provides substantially similar air flow adjacent components of the electronic device in response to different configurations of the adjacent components.

20. The system of claim 18, further comprising:
at least one means for sensing the different configurations of the adjacent components;
means for automatically notifying a user how to change the means for adjusting based on input from the at least one sensing means; and
means for automatically moving the means for adjusting based on input from the at least one sensing means.
